(19) United States
(12) Patent Application Publication
(10) Pub. No.: US 2017/0338184 A1
(43) Pub. Date: Nov. 23, 2017

(54) METHOD OF DICING INTEGRATED CIRCUIT WAFERS

(71) Applicant: Texas Instruments Incorporated, Dallas, TX (US)

(72) Inventor: Shoichi Iriguchi, Beppu (JP)

(21) Appl. No.: 15/159,046

(22) Filed: May 19, 2016

(51) Int. Cl. H01L 23/544; H01L 21/683; H01L 21/78

(52) U.S. Cl. CPC H01L 23/544; H01L 21/78; H01L 21/6836; H01L 2223/5446; H01L 2221/68327

(57) ABSTRACT

A method of dicing an integrated circuit wafer by partially sawing the scribe street from the backside of the wafer and then completing sawing the scribe street from the front side of the wafer. A method of dicing an integrated circuit wafer by backgrinding the wafer prior to partially sawing the scribe street from the backside of the wafer and then completing sawing the scribe street from the front side of the wafer.

### FIELD

This disclosure relates to the field of integrated circuits. More particularly, this disclosure relates to the dicing of integrated circuit wafers.

### BACKGROUND

The die (also called integrated circuit chips) on an integrated circuit wafer are separated from each other by scribe streets. The term “scribe street” was established when scribe streets between the die provided room for a diamond pointed scribe to scratch the surface of the silicon wafer. By applying slight pressure to the wafer on either side of the scratched wafer, the wafer could be broken along the silicon crystal planes separating the die on either side of the scribe street.

The conventional method used to separate die today is to saw through the scribe streets using dicing saw. This dicing method is illustrated in FIGS. 1 and 2.

As shown in FIG. 1, after the integrated circuit (IC) manufacturing is completed, the IC wafer 104 with the integrated circuits 106 separated by scribe streets 108 on the top surface is mounted on dicing tape 102.

A dicing saw 110 is then used to saw the rest of the way through the wafer 104 along the scribe streets 108 to separate the IC die 112.

The width of the scribe street 108 has become narrower as the dimensions of geometries on IC chips have scaled. This enables more die on the wafer. Dicing saw blades 110 have gotten narrower to accommodate the narrower scribe streets 108. The thickness of silicon that a dicing saw blade 110 can cut through is limited by the width of the dicing saw blade 110. The dicing saw blade 110 must be wider to saw through thicker silicon.

As is illustrated in FIG. 3, one method that enables the use of narrower scribe streets is to thin the wafer 120 using back grind prior to applying the dicing tape 102 to the backside of the wafer 120. Since the wafer 120 is now thinner a narrower dicing saw blade 114 may be used as is shown in FIG. 4.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A method of dicing an integrated circuit wafer by partially sawing the scribe street from the backside of the wafer and then completing sawing the scribe street from the front side of the wafer. A method of dicing an integrated circuit wafer by backgrinding the wafer prior to partially sawing the scribe street from the backside of the wafer and then completing sawing the scribe street from the front side of the wafer.

### DESCRIPTION OF THE VIEWS OF THE DRAWINGS

FIG. 1 (Prior art) is a cross section of an integrated circuit wafer mounted on dicing tape pre dicing.

FIG. 2 (Prior art) is a cross section of an integrated circuit wafer mounted on dicing tape post dicing.

FIG. 3 (Prior art) is a cross section of an integrated circuit wafer mounted on dicing tape pre dicing.

FIG. 4 (Prior art) is a cross section of an integrated circuit wafer mounted on dicing tape post dicing.

FIG. 5 (Prior Art) is a cross section of a dicing saw cutting the scribe street between die on an integrated circuit wafer.

FIG. 6A through FIG. 6C are cross sections of the integrated circuit wafer depicted in successive stages of dicing using an embodiment dicing method.

FIG. 7A through FIG. 7E are cross sections of another example integrated circuit containing a thin film resistor, depicted in successive stages of fabrication.

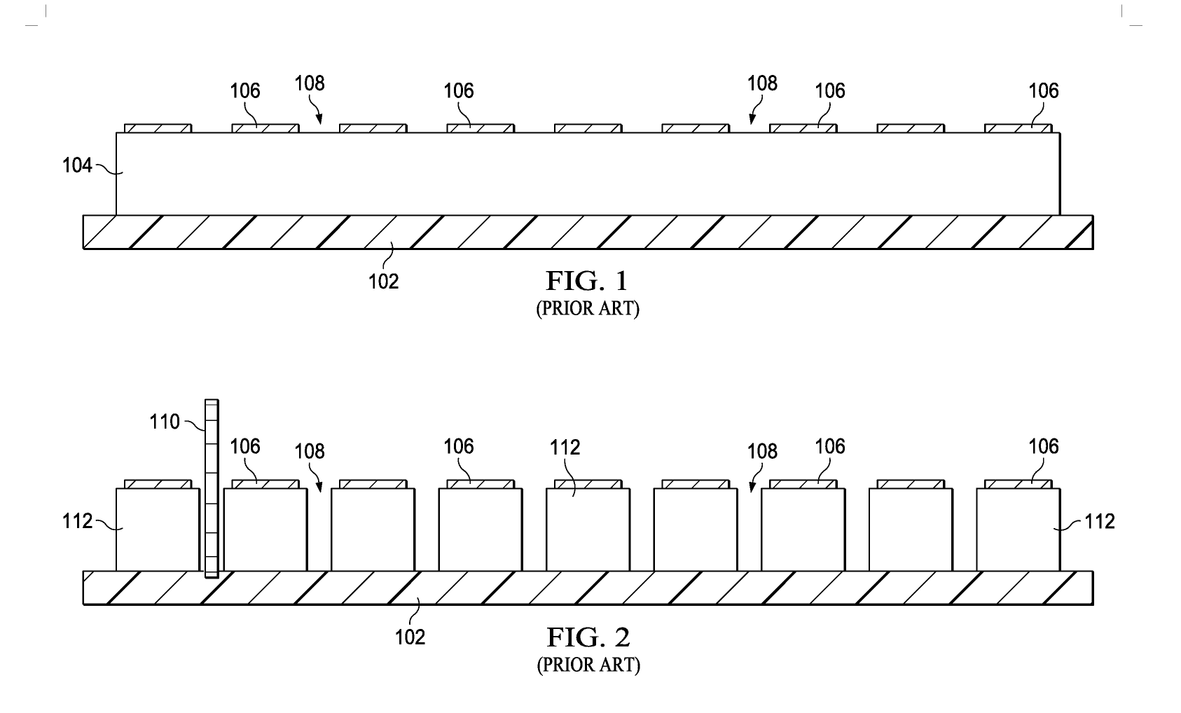

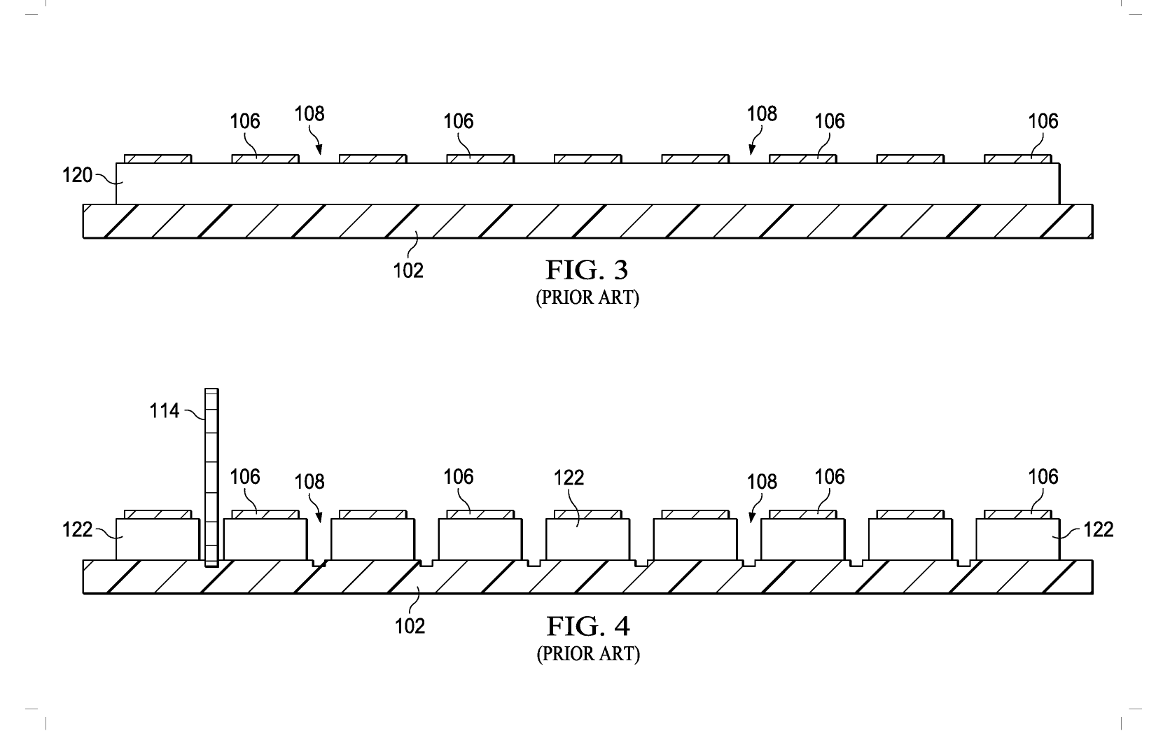

### DETAILED DESCRIPTION OF EXAMPLE EMBODIMENTS

Embodiments of the disclosure are described with reference to the attached figures. The figures are not drawn to scale and they are provided merely to illustrate the disclosure. Several aspects of the embodiments are described below with reference to example applications for illustration. It should be understood that numerous specific details, relationships, and methods are set forth to provide an understanding of the disclosure. One skilled in the relevant art, however, will readily recognize that the disclosure can be practiced without one or more of the specific details or with other methods. In other instances, well-known structures or operations are not shown in detail to avoid obscuring the disclosure. The embodiments are not limited by the illustrated ordering of acts or events, as some acts may occur in different orders and/or concurrently with other acts or events. Furthermore, not all illustrated acts or events are required to implement a methodology in accordance with the present disclosure.

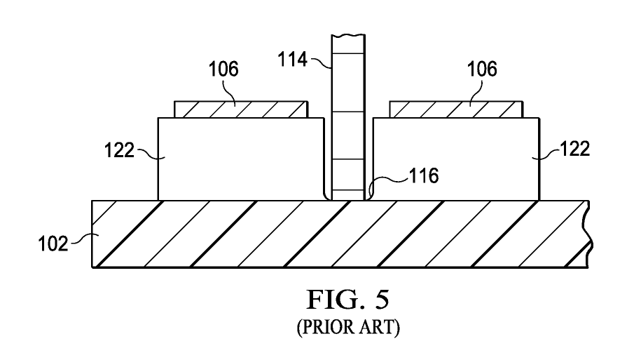

The current method of sawing the die apart on IC wafers has several drawbacks. One problem is that the edge of the dicing saw blade accumulates adhesive and silicon saw dust on the edge of the dicing saw blade when it saws through the wafer and into the dicing tape. This limits the lifetime of the dicing blade and also introducing chip outs and cracks to form in the edges of the die. To limit the exposure of the edge of the dicing blade 114 to dicing tape 102 adhesive the dicing saw blade 114 may be stopped as soon as the bottom of the silicon wafer 102 is sawed through as is illustrated in FIG. 5. This may form a sharp corner 116 at the bottom corner of the die 122 which is prone to chipping and cracking.

Another issue with the current method is that the width of the scribe street is limited by the width of the dicing blade. The width of the dicing blade is determined by the thickness of the silicon to be sawed. To reduce the width of the dicing saw blade, the wafers may be thinned using back grinding prior to sawing. The thinned wafers are difficult to handle and are prone to breakage. The width of the scribe street in this case is limited by the minimum thickness of the wafer that can be handled without breakage.

The above described issues with the current method are exacerbated as the die size becomes smaller. Die sizes less than 1 mm square are especially problematic.

With small die and additional problem of die fly emerges. As the die size becomes smaller, the contact area between the surface of the die and the adhesive on the dicing tape is reduced. The rotating dicing saw blade may cause the die to be lifted off the dicing tape and to fly across the room (die fly.)

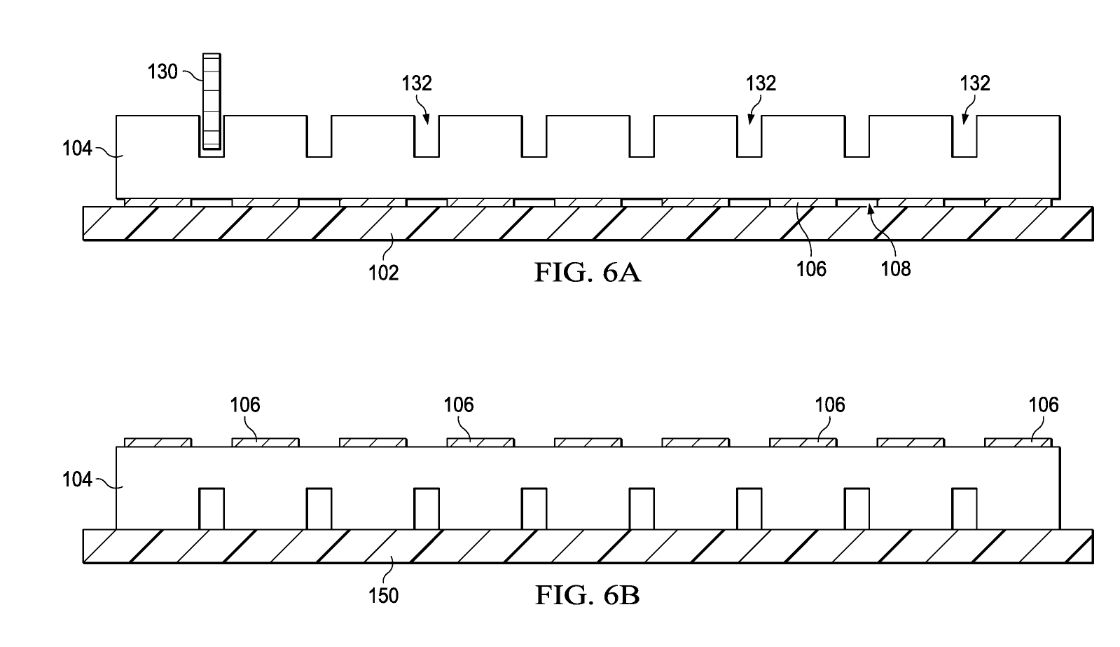

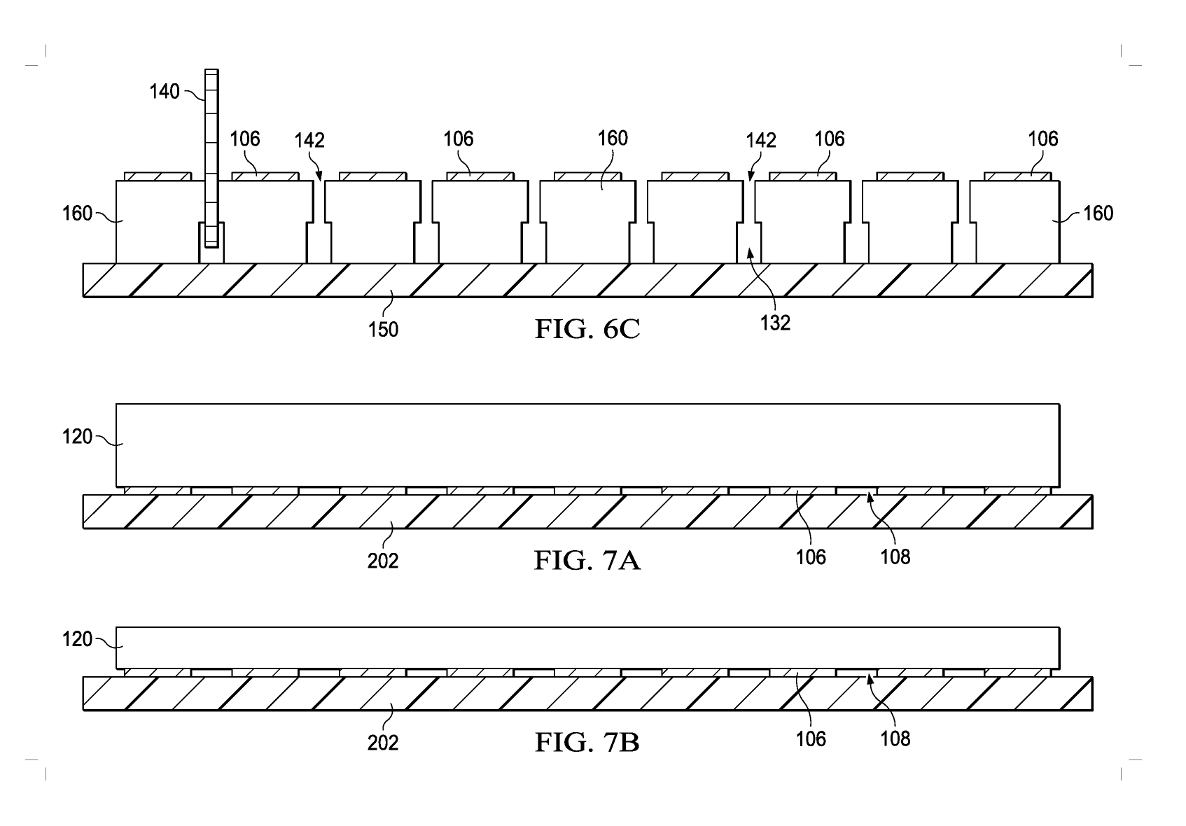

A method for dicing wafers that avoids the problem with the current method of sawing wafers is illustrated in FIGS. 6A, 6B, and 6C.

As shown in 6A, and integrated circuit wafer 104 with integrated circuits 106 separated by scribe streets 108 is glued face down on dicing tape 102. The scribe streets 108 are then partially sawed through the wafer 104 from the backside of the wafer 104. The width of the dicing saw blade 130 used is determined by the thickness of the silicon to be sawed through from the backside of the wafer 104. The width of the scribe street 132 partially sawed from the backside of the wafer 104 may be greater than the width of the scribe street 108 on the front side of the wafer 104. The depth of the sawed backside trench may be between 40% and 60% the thickness of the integrated circuit wafer 104. In an example, the width of the saw blade is about 15 um and the width of the scribe street is about 52 um.

As shown in FIG. 6B, the dicing tape 102 is removed from the front side of the wafer and another dicing tape 150 is applied to the backside of the wafer 104.

In FIG. 6C, another dicing saw blade 140 is then used to complete the sawing of the silicon through the wafer 104 along the scribe street 132 to separate the IC die 160.

This embodiment procedure for sawing the scribe streets affords several advantages over conventional methods.

First the edge of the dicing blades 130 and 140 never come into contact with the adhesive on the dicing tapes 102 and 150. This prevents adhesive and silicon saw dust from accumulating on the dicing blades, 130 and 140. This significantly reduces the number of rip outs and cracks formed on the edges of the die during sawing. In addition, the lifetime of the dicing blades 130 and 140 is significantly lengthened.

Secondly, this embodiment procedure enables scaling of the width of the scribe street 108 to smaller dimensions. By partially sawing the scribe street 108 from the backside of the wafer 104, a reduced thickness of silicon remains to be sawed from the front side of the wafer 104. Reducing the thickness of silicon that remains to be sawed from the front side enables a reduction in the width of the dicing blade 140 and consequently enables a reduction in the width of the scribe street 108.

Additionally, since the scribe is sawed completely through without touching the dicing tape 102 adhesive no sharp corners are formed at the bottom of the die that are susceptible to cracking and chipping.

Additionally, since this method enables a thicker wafer may be used with narrow scribe streets, wafer breakage is reduced.

Additionally, for some wafers, the back grinding step to reduce wafer thickness prior to dicing may be eliminated thus reducing cost.

Additionally, die smaller than 1 mm square especially benefit from the embodiment dicing method. Small die may be separated by dicing using sawing with a significant reduction in side wall chipping, back wall chipping, and die fly. This method enabled dicing die with 0.3 mm by 0.3 mm with little chipping and without die fly.

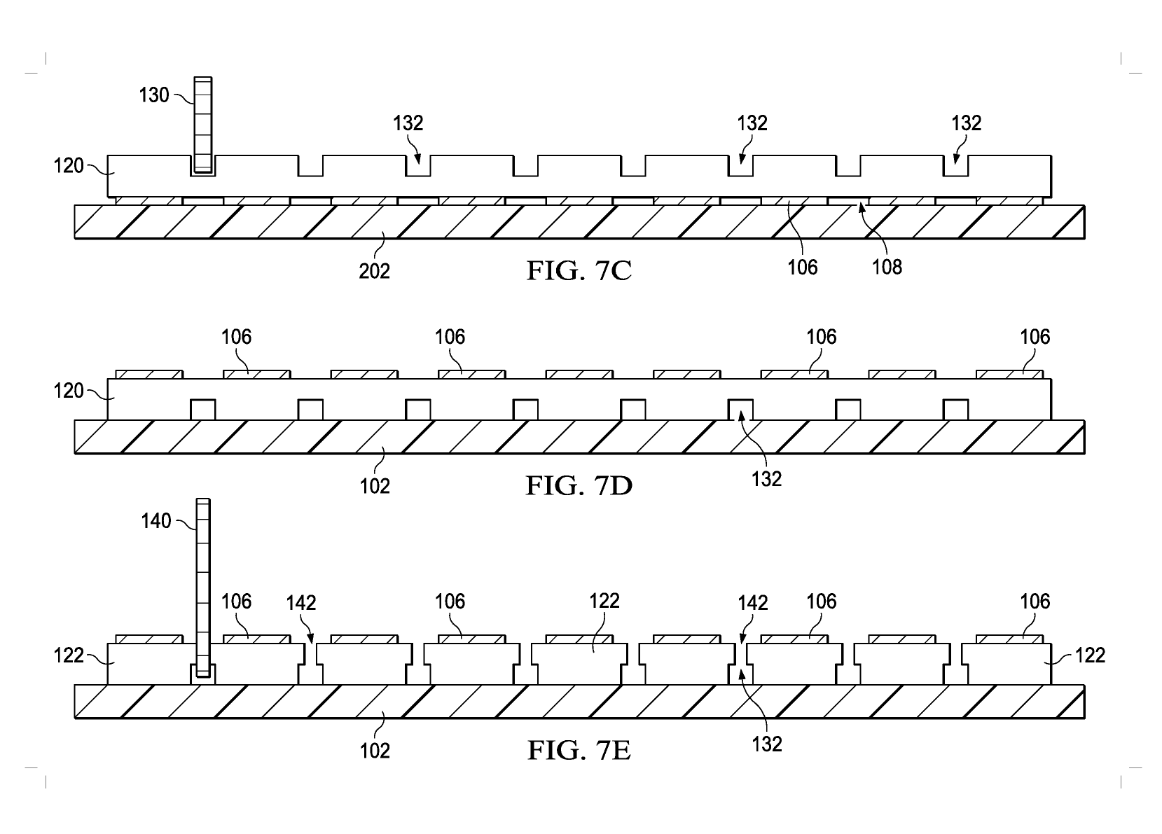

As is illustrated in FIGS. 7A, 7B, 7C, 7D, and 7E the wafer thickness may be reduced by back grinding prior to implementing the embodiment dicing procedure to enable the use of even narrower scribe lanes. The integrated circuit wafer may be reduced in thickness by 30% to 60% by backgrinding prior to sawing.

In FIG. 7A, back grind tape 202 is applied to the front side of the wafer 120. Integrated circuits 106 on the front side of the wafer 120 are separated by scribe streets 108.

In FIG. 7B the wafer 120 is thinned by back grinding. The integrated circuit wafer may be reduced in thickness by 30% to 60% by backgrinding prior to sawing.

In FIG. 7C the scribe streets 108 are partially sawed through the wafer 120 using a dicing saw 130. The width 132 of the scribe partially sawed from the backside may be wider than the scribe street 108 on the front side of the wafer 120.

The back grind tape 202 is removed from the front side of the wafer 120 and dicing tape 102 is applied to the backside of the wafer 120 as shown in FIG. 7D.

In FIG. 7E, the scribe street 108 is completely sawed through 142 the wafer 102 from the front side to separate each IC die 122. Since the remaining silicon is thin, a dicing blade 140 with a narrow width may be used.

Thinning the wafer prior to implementing the embodiment dicing procedure may enable an even narrower scribe street to be used than is possible with conventional dicing methods.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present disclosure should not be limited by any of the above described embodiments. Rather, the scope of the disclosure should be defined in accordance with the following claims and their equivalents.

1-19. (canceled)

20. A method for dicing an integrated circuit wafer, comprising:
applying a first tape to a first side of the wafer, the first side including integrated circuits;
sawing the wafer from an opposite second side of the wafer to a first depth using a first dicing blade with a first thickness;
removing the first tape;
applying a second tape to the opposite second side; and
sawing the wafer from the first side till an end of the first depth using a second dicing blade with a second thickness, wherein the second dicing blade remains at a distance from the second tape during sawing the wafer from the first side.

21. The method of claim 20, wherein the second thickness is less than the first thickness.

22. The method of claim 20 further comprising back grinding the wafer to reduce a thickness of the integrated circuit wafer.

23. The method of claim 20, wherein sawing the wafer from an opposite second side and sawing the wafer from the first side do not saw the first tape and the second tape.

24. The method of claim 20, wherein sawing the wafer from the opposite second side and sawing the wafer from the first side are along scribe streets of the wafer.

25. The method of claim 20, wherein the first tape and the second tape are dicing tapes.

26. The method of claim 20, wherein the first depth is less than a thickness of the wafer.

27. The method of claim 26, wherein the first depth is between 40% and 60% thickness of the wafer.

28. The method of claim 20, wherein a width of the scribe street is at least about 52 μm.

29. A method for dicing an integrated circuit wafer, comprising:
applying a back grinding tape to a first side of the wafer;
back grinding the wafer;
sawing the wafer from an opposite second side of the wafer to a first depth using a first dicing blade;
removing the back grinding tape;
applying a second tape to the opposite second side; and
sawing the wafer from the first side till an end of the first depth using a second dicing blade with a second thickness, wherein the second dicing blade remains at a distance from the second tape during sawing the wafer from the first side.

30. The method of claim 29, wherein the first dicing blade has a first thickness and the second dicing blade has a second thickness, second thickness being less than the first thickness.

31. The method of claim 29, wherein sawing the wafer from the opposite second side and sawing the wafer from the first side do not saw the back grinding tape and the second tape.

32. The method of claim 29, wherein sawing the wafer from an opposite second side and sawing the wafer from the first side are along scribe streets of the wafer.

33. The method of claim 29, wherein the first depth is less than a thickness of the wafer.

34. The method of claim 33, wherein the first depth is between 40% and 60% thickness of the wafer.

35. A method for dicing an integrated circuit wafer, comprising:
applying a first tape to a first side of the wafer, the first side including integrated circuits;
sawing the wafer from an opposite second side of the wafer to a first depth using a first dicing blade;
removing the first tape;
applying a second tape to the opposite second side; and
sawing the wafer from the first side till an end of the first depth using a second dicing blade, wherein the second dicing blade does not contact the second tape during sawing the wafer from the first side.

36. The method of claim 35, wherein the wafer includes a plurality of dies and sawing the wafer from the first side separates each of the plurality of dies.

37. The method of claim 35, wherein a size of each of the plurality of dies is greater than about 0.3 mm by 0.3 mm.

38. The method of claim 35, wherein the first dicing blade has a first thickness and the second dicing blade has a second thickness, second thickness being lesser than the first thickness.
